(19) United States
(12) Patent Application Publication
(10) Pub. No.: US 2007/0278696 A1
(43) Pub. Date: Dec. 6, 2007

(54) Stackable semiconductor package

(76) Inventors: Yung-Li Lu, Kaohsiung (TW); Cheng-Yin Lee, Kaohsiung (TW); Ying-Tsai Yeh, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/636,986

(22) Filed: Dec. 12, 2006

(30) Foreign Application Priority Data
May 30, 2006 (TW) 095119251

(51) Int. Cl. H01L 23/52

(52) U.S. Cl. 257/777

(57) ABSTRACT

The present invention relates to a stackable semiconductor package including a first substrate, a chip, a low modules film, a second substrate, a plurality of first wires, and a first molding compound. The chip is disposed on the first substrate. The low modules film is disposed on the chip. The second substrate is disposed on the low modules film. The area of the low modules film is adjusted according to the area of the second substrate, so as to support the second substrate. The first wires electrically connect the first substrate and the second substrate. Some pads of the second substrate are exposed outside the first molding compound. Therefore, the overhang portion of the second substrate will not shake or sway during a wire bonding process, and the area of the second substrate can be increased to receive more devices disposed thereon. In addition, the thickness of the second substrate can be reduced, so as to reduce the overall thickness of the stackable semiconductor package.

### BACKGROUND OF THE INVENTION

1. Field of the Invention

The present invention relates to a stackable semiconductor package, more particularly to a stackable semiconductor package containing a low modules film.

2. Description of the Related Art

FIG. 1 is a schematic sectional view of a conventional stackable semiconductor package. The conventional stackable semiconductor package 1 includes a first substrate 11, a chip 12, a spacer 13, a second substrate 14, a plurality of first wires 15, and a first molding compound 16.

The first substrate 11 has a first surface 111 and a second surface 112. The chip 12 has a first surface 121 and a second surface 122. The second surface 122 of the chip 12 is adhered to the first surface 111 of the first substrate 11 by the use of an adhesive layer 17. The first surface 121 of the chip 12 is electrically connected to the first surface 111 of the first substrate 11 via a plurality of second wires 18. The spacer 13 is adhered to the first surface 121 of the chip 12. The second substrate 14 has a first surface 141 and a second surface 142. The second surface 142 of the second substrate 14 is adhered to the spacer 13. The first surface 141 of the second substrate 14 has a plurality of first pads 143 and a plurality of second pads 144 disposed thereon. From a top view, the area of the second substrate 14 is larger than that of the chip 12. Therefore, the spacer 13 is needed to support the second substrate 14 to prevent the second substrate 14 from pressing the second wires 18.

The first wires 15 electrically connect the first pads 143 of the second substrate 14 to the first surface 111 of the first substrate 11. The first molding compound 16 encapsulates the first surface 111 of the first substrate 11, the chip 12, the second wires 18, the spacer 13, a portion of the second substrate 14, and the first wires 15, and the second pads 144 on the first surface 141 of the second substrate 14 are exposed outside the first molding compound 16, thereby forming a mold area opening 19. Under ordinary circumstances, the conventional stackable semiconductor package 1 further includes another package 20 or other devices stacked at the mold area opening 19, wherein solder balls 201 of the package 20 are electrically connected to the second pads 144 of the second substrate 14.

The disadvantages of the conventional stackable semiconductor package 1 are described as follows. First, the spacer 13 is a plate, which is precut into the desired size and then is coated with an adhesive to be adhered to the chip 12. After that, the second substrate 14 is adhered to the spacer 13. The above steps are complicated, and also present difficulties in terms of alignment. Secondly, the spacer 13 cannot contact the second wires 18, so the area thereof must be smaller than that of the chip 12. However, as the area of the second substrate 14 is larger than that of the chip 12, the second substrate 14 partially extends beyond the spacer 13, thus forming an overhang portion. Under common circumstances, the first pads 143 are disposed at the overhang portion (i.e., the periphery of the corresponding position of the spacer 13 or the chip 12), and the distance between the corresponding position of the first pads 143 and the edge of the spacer 13 is defined as an overhang length L1. Experimental results show that during the wire bonding process, when the overhang length L1 is more than three times greater than the thickness T1 of the second substrate 14, the overhang portion may shake or sway, which is disadvantageous for the wire bonding process. Further, during the wire bonding process, when the second substrate 14 is subjected to an excessive downward stress, the second substrate 14 may be cracked. Then, due to the above risk of swaying, shaking or cracking, the overhang portion cannot be too long, which limits the area of the second substrate 14, thus further limiting the layout space of the second pads 144 on the first surface 141 of the second substrate 14 exposed at the mold area opening 19. Finally, in order to overcome the above danger of swaying, shaking or cracking, the second substrate 14 cannot be too thin, such that the overall thickness of the conventional stackable semiconductor package 1 cannot be effectively reduced.

Therefore, it is necessary to provide a stackable semiconductor package to solve the above problems.

### SUMMARY OF THE INVENTION

The objective of the present invention is to provide a stackable semiconductor package, which comprises a first substrate, a chip, a low modules film, a second substrate, a plurality of first wires, and a first molding compound. The first substrate has a first surface and a second surface. The chip is disposed on the first surface of the first substrate, and is electrically connected thereto. The low modules film is disposed on the chip. The second substrate is disposed on the low modules film and has a first surface and a second surface. The first surface of the second substrate has a plurality of first pads and a plurality of second pads disposed thereon. The area of the low modules film can be adjusted according to the area of the second substrate, so as to support the second substrate.

The first wires electrically connect the first pads of the second substrate to the first surface of the first substrate. The first molding compound encapsulates the first surface of the first substrate, the chip, the low modules film, a portion of the second substrate, and the first wires, and the second pads on the first surface of the second substrate are exposed outside the first molding compound. Therefore, swaying, shaking, or cracking of the overhang portion of the second substrate will not occur during a wire bonding process, and the area of the second substrate can be increased to receive more devices disposed thereon. In addition, the thickness of the second substrate can be reduced, so as to reduce the overall thickness of the stackable semiconductor package.

### BRIEF DESCRIPTION OF THE DRAWINGS

FIG. 1 is a schematic sectional view of a conventional stackable semiconductor package;

FIG. 2 is a schematic sectional view of the stackable semiconductor package according to the first embodiment of the present invention;

FIG. 3 is a schematic sectional view of the stackable semiconductor package according to the second embodiment of the present invention;

FIG. 4 is a schematic sectional view of the stackable semiconductor package according to the third embodiment of the present invention; and

FIG. 5 is a schematic sectional view of the stackable semiconductor package according to the fourth embodiment of the present invention.

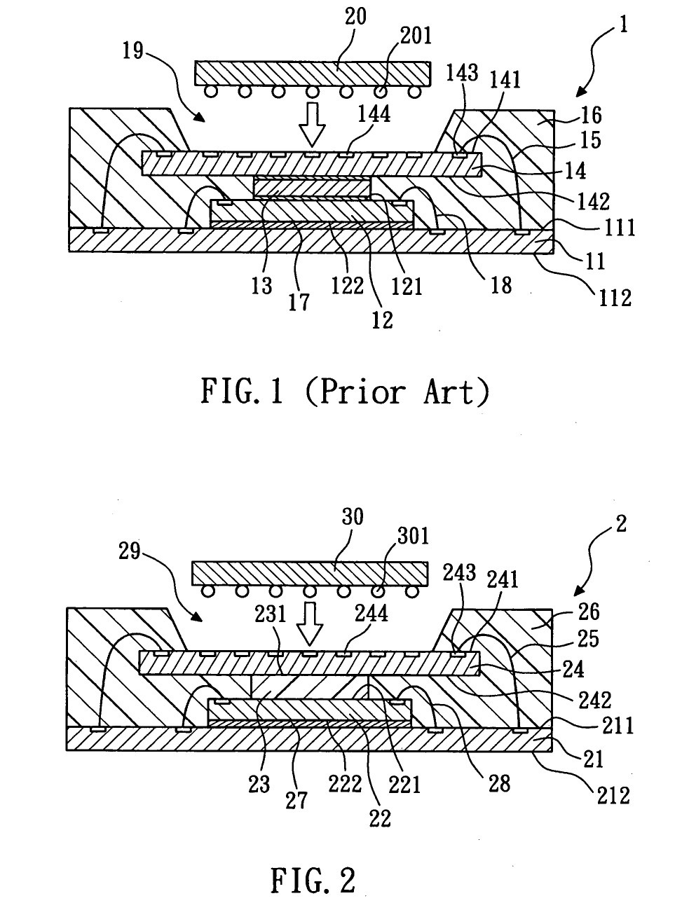

### DETAILED DESCRIPTION OF THE INVENTION

FIG. 2 shows a schematic sectional view of the stackable semiconductor package according to the first embodiment of the present invention. The stackable semiconductor package 2 includes a first substrate 21, a chip 22, a low modules film 23, a second substrate 24, a plurality of first wires 25, and a first molding compound 26.

The first substrate 21 has a first surface 211 and a second surface 212. The chip 22: has a first surface 221 and a second surface 222. The second surface 222 of the chip 22 is adhered to the first surface 211 of the first substrate 21 by the use of an adhesive layer 27. The first surface 221 of the chip 22 is electrically connected to the first surface 211 of the first substrate 21 via a plurality of second wires 28. The low modules film 23 is disposed on the first surface 221 of the chip 22. The second substrate 24 has a first surface 241 and a second surface 242. The second surface 242 of the second substrate 24 is adhered to the low modules film 23. The first surface 241 of the second substrate 24 has a plurality of first pads 243 and a plurality of second pads 244 disposed thereon.

In the present embodiment, the low modules film 23 is a tape-type thermosetting resin composed of resins (including epoxy resin and phenol resin), acrylic rubber, and Si filler. The low modules film 23 used in the present embodiment is the model FH-WP manufactured by Hitachi Chemical Co., Ltd. The low modules film 23 obtains a high elastic modulus after curing, so as to support the second substrate 24. The low modules film 23, due to being adhesive, is first formed on the second surface 242 of the second substrate 24, then is disposed on the first surface 221 of the chip 22, and then is cured. However, it should be noted that the horizontal height of the upper surface 231 of the low modules film 23 after curing must be higher than the top of the second wires 28.

The first wires 25 electrically connect the first pads 243 of the second substrate 24 to the first surface 211 of the first substrate 21. The first molding compound 26 encapsulates the first surface 211 of the first substrate 21, the chip 22, the second wires 28, the low modules film 23, a portion of the second substrate 24, and the first wires 25, and the second pads 244 on the first surface 241 of the second substrate 24 are exposed outside the first molding compound 26, thereby forming a mold area opening 29. Under ordinary circumstances, the stackable semiconductor package 2 further includes another package 30 or other devices stacked at the mold area opening 29, wherein solder balls 301 of the package 30 are electrically connected to the second pads 244 of the second substrate 24.

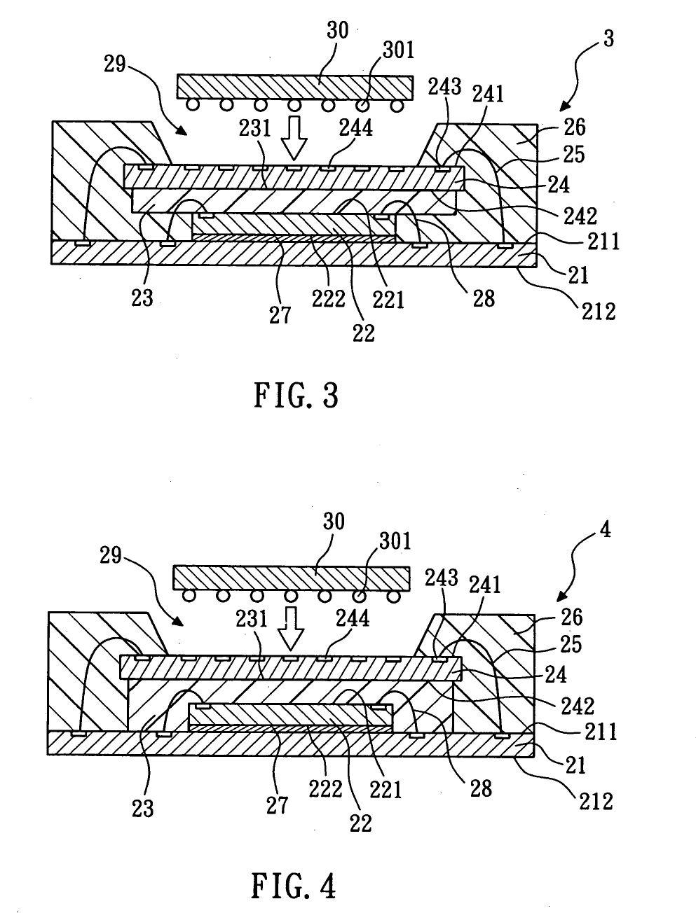

FIG. 3 is a schematic sectional view of the stackable semiconductor package according to the second embodiment of the present invention. The stackable semiconductor package 3 of the present embodiment is similar to the stackable semiconductor package 2 of the first embodiment, in which the identical devices are indicated by the same reference numerals. The difference therebetween lies in the size of the second substrate 24 and low modules film 23. The second substrate 24 of the present embodiment is appreciably larger than that of the first embodiment, and the area of the low modules film 23 can be adjusted according to the area of the second substrate 24. That is, the low modules film 23 can be extended to be close to the area of the second substrate 24 and cover a portion of the second wires 28. When heated, the low modules film 23 may generate very low modules, which are sufficient to absorb the stress of the second wires 28 without impacting the second wires 28. As such, a supporting effect better than that of the first embodiment can be achieved, so as to support the second substrate 24 with a large size. In the present embodiment, the first pads 243 are disposed in the periphery of the corresponding position of the chip 22. The distance between the corresponding position of the first pads 243 and the periphery of the chip 22 is defined as an overhang length L2. Due to the support of the low modules film 23, the overhang length L2 can be more than three times greater than the thickness T2 of the second substrate 24, and meanwhile the overhang portion does not sway during the wire bonding process.

FIG. 4 shows a schematic sectional view of the stackable semiconductor package according to the third embodiment of the present invention. The stackable semiconductor package 4 of the present embodiment is similar to the stackable semiconductor package 2 of the first embodiment, in which the identical devices are indicated by the same reference numerals. The difference therebetween lies in the size of the low modules film 23. In the present embodiment, the area of the second substrate 24 is larger than that of the chip 22, and the area of the low modules film 23 can be adjusted according to the area of the second substrate 24. That is, the low modules film 23 is extended between the first surface 211 of the first substrate 21 and the second surface 242 of the second substrate 24, and completely covers the second wires 28 and the chip 22. As such, a supporting effect better than that of the second embodiment is achieved, thus preventing the second substrate 24 from swaying during the wire bonding process, and the thin second substrate 24 with a large size can be adopted.

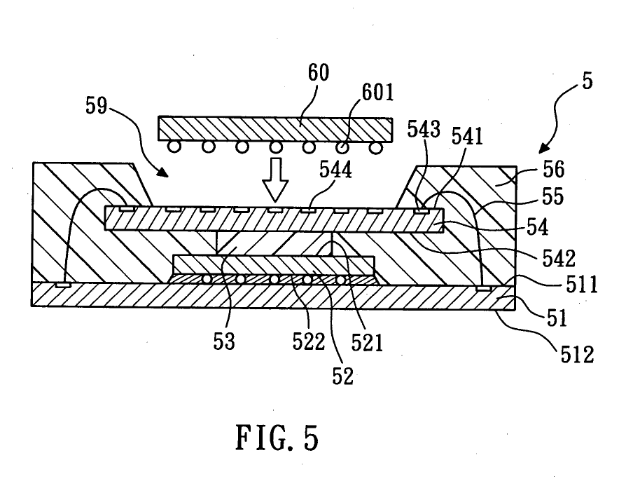

FIG. 5 is a schematic sectional view of the stackable semiconductor package according to the fourth embodiment of the present invention. The stackable semiconductor package 5 includes a first substrate 51, a chip 52, a low modules film 53, a second substrate 54, a plurality of first wires 55, and a first molding compound 56.

The first substrate 51 has a first surface 511 and a second surface 512. The chip 52 has a first surface 521 and a second surface 522. The second surface 522 of the chip 52 is attached to the first surface 511 of the first substrate 51 in the manner of a flip-chip bonding. The low modules film 53 is disposed on the first surface 521 of the chip 52. The second substrate 54 has a first surface 541 and a second surface 542. The second surface 542 of the second substrate 54 is adhered to the low modules film 53. The first surface 541 of the second substrate 54 has a plurality of first pads 543 and a plurality of second pads 544 disposed thereon.

The first wires 55 electrically connect the first pads 543 of the second substrate 54 to the first surface 511 of the first substrate 51. The first molding compound 56 encapsulates the first surface 511 of the first substrate 51, the chip 52, the low modules film 53, a portion of the second substrate 54, and the first wires 55, and the second pads 544 on the first surface 541 of the second substrate 54 are exposed outside the first molding compound 56, thereby forming a mold area opening 59. Under ordinary circumstances, the stackable semiconductor package 5 further includes another package 60 or other devices stacked at the mold area opening 59, wherein solder balls 601 of the package 60 are electrically connected to the second pads 544 of the second substrate 54.

Similarly, the low modules film 53 can also be extended to be close to the area of the second substrate 54 just like the low modules film 23 shown in FIG. 3, or extended between the first surface 511 of the first substrate 51 and the second surface 542 of the second substrate 54 like the low modules film 23 shown in FIG. 4.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A stackable semiconductor package, comprising:
a first substrate having a first surface and a second surface;
a chip disposed on the first surface of the first substrate, and electrically connected to the first surface of the first substrate;
a low modules film disposed on the chip;
a second substrate disposed on the low modules film, and having a first surface and a second surface, wherein the first surface of the second substrate has a plurality of first pads and a plurality of second pads disposed thereon, and the area of the low modules film is adjusted according to the area of the second substrate, so as to support the second substrate;
a plurality of first wires electrically connecting the first pads of the second substrate to the first surface of the first substrate; and
a first molding compound encapsulating the first surface of the first substrate, the chip, the low modules film, a portion of the second substrate, and the first wires, and exposing the second pads on the first surface of the second substrate.

2. The stackable semiconductor package as claimed in claim 1, further comprising a plurality of second wires for electrically connecting the chip and the first surface of the first substrate, wherein the chip is adhered to the first surface of the first substrate and the horizontal height of the upper surface of the low modules film is higher than the top of the second wires.

3. The stackable semiconductor package as claimed in claim 2, wherein the area of the second substrate is larger than that of the chip, and the low modules film is extended to the second wires and covers the second wires.

4. The stackable semiconductor package as claimed in claim 2, wherein the area of the second substrate is larger than that of the chip, and the low modules film is extended between the first surface of the first substrate and the second surface of the second substrate and completely covers the second wires and the chip.

5. The stackable semiconductor package as claimed in claim 1, wherein the chip is a flip-chip attached to the first surface of the first substrate.

6. The stackable semiconductor package as claimed in claim 5, wherein the area of the second substrate is larger than that of the chip, and the low modules film is extended between the first surface of the first substrate and the second surface of the second substrate and completely covers the chip.

7. The stackable semiconductor package as claimed in claim 1, wherein the low modules film is of a tape type.

8. The stackable semiconductor package as claimed in claim 1, wherein the low modules film is a thermosetting resin.

9. The stackable semiconductor package as claimed in claim 1, wherein the first pads are disposed in the periphery of a corresponding position of the chip.

10. The stackable semiconductor package as claimed in claim 9, wherein the distance between the corresponding position of the first pads and the periphery of the chip is defined as an overhang length which is more than three times greater than the thickness of the second substrate.
